(19) United States
(12) Patent Application Publication
(10) Pub. No.: US 2026/0299012 A1
(43) Pub. Date: Oct. 1, 2026

(54) DERIVING MULTIPLE STEP AND IMPULSE RESPONSES FROM PULSE RESPONSE ANALYSIS

(71) Applicant: Tektronix, Inc., Beaverton, OR (US)

(72) Inventor: Kan Tan, Portland, OR (US)

(21) Appl. No.: 19/564,547

(22) Filed: Mar. 12, 2026

Related U.S. Application Data
(60) Provisional application No. 63/775,571, filed on Mar. 21, 2025.

(51) Int. Cl. G01R 31/28; G01R 29/02

(52) U.S. Cl. CPC G01R 31/2846; G01R 29/02; G01R 31/2837

(57) ABSTRACT

A test and measurement instrument includes a port to allow the instrument to receive a signal from a device under test (DUT), one or more processors configured to execute code that causes the one or more processors to: acquire a waveform from the signal, derive a pattern waveform from the waveform using one of either hardware or software clock recovery, perform linear fit pulse response extraction on the pattern waveform to extract one or more linear fit pulse responses (LFPRs), determine at least one of one or more rising step responses and one or more falling step responses from each of the one or more LFPRs, evaluate the DUT based upon at least one of the one or more rising step responses and the one or more falling step responses, and adjust one or more of operation and design of the DUT based upon the evaluation.

### CROSS-REFERENCE TO RELATED APPLICATIONS

This disclosure is a non-provisional of and claims benefit from U.S. Provisional Application No. 63/775,571, titled “DERIVING MULTIPLE STEP AND IMPULSE RESPONSES FROM PULSE RESPONSE ANALYSIS,” filed on Mar. 21, 2025, the disclosure of which is incorporated herein by reference in its entirety.

### TECHNICAL FIELD

This disclosure relates to test and measurement instruments, and more particularly to deriving multiple step and impulse responses from pulse response analysis for a test and measurement instrument.

### BACKGROUND

As signal speeds continue to increase, signal modulation schemes have become more complex to accommodate these advancements. Technologies, such as Peripheral Component Interconnect Express (PCIe) Gen7 and 400G Ethernet, are now employing PAM4 signaling in lieu of non-return-to-zero (NRZ) signaling. The extraction of multiple pulses from PAM4 signals offers enhanced insights for calibration and for measurements, compared to single pulse extraction.

For example, U.S. patent application Ser. No. 18/754,871, published as U.S. Patent Publication No. 20240004014, “MULTIPLE PULSE EXTRACTION FOR TRANSMITTER CALIBRATION,” filed Jun. 26, 2024, describes a method for extracting multiple pulses from waveforms for transmitter calibration, which is incorporated by reference in its entirety herein. In another example, extraction of linear fit pulse response can be used to optimize filter coefficients used in transmitters, as described in U.S. Pat. No. 11,765,002, “EXPLICIT SOLUTION FOR DFE OPTIMIZATION WITH CONSTRAINTS,” issued Sep. 19, 2023, which is incorporated by reference in its entirety herein.

Recent advances have introduced methodologies for extracting multiple pulse responses from Pulse Amplitude Modulation 4-level (PAM4) signaling, offering enhanced analytical insights.

The analysis of step responses and impulse responses reveals distinct information about the signals that pulse responses alone may not provide. Step responses are instrumental in determining the rise time of signals and are also pivotal for Time Domain Reflectometry (TDR) assessments of system impedance profiles. On the other hand, impulse responses, when transformed into the frequency domain via Fourier transform, provides crucial details about frequency-dependent channel loss and inter-symbol interference (ISI).

### BRIEF DESCRIPTION OF THE DRAWINGS

FIG. 1 shows an embodiment of a test and measurement device capable of deriving multiple step and impulse responses from waveforms.

FIG. 2 shows an example of a 4-level pulse-amplitude modulation (PAM4) pattern waveform.

FIG. 3 shows a single extracted linear fit pulse response.

FIG. 4 shows a rising step response derived from the single extracted linear fit pulse response of FIG. 3.

FIG. 5 shows a falling step response derived from the single extracted linear fit pulse response of FIG. 3.

FIG. 6 shows multiple pulses extracted from a pattern waveform.

FIG. 7 shows multiple rising step responses derived from the linear fit pulse responses of FIG. 6.

FIG. 8 shows multiple falling step responses derived from the linear fit pulse responses of FIG. 6.

### DETAILED DESCRIPTION

The present embodiments involve a test and measurement instrument and methodology that uses the extraction of the initial Linear Fit Pulse Response (LFPR), from which step responses and impulse responses are derived. Subsequently, methodologies for deriving multiple pulses, along with comprehensive step responses and impulse responses, are elaborated.

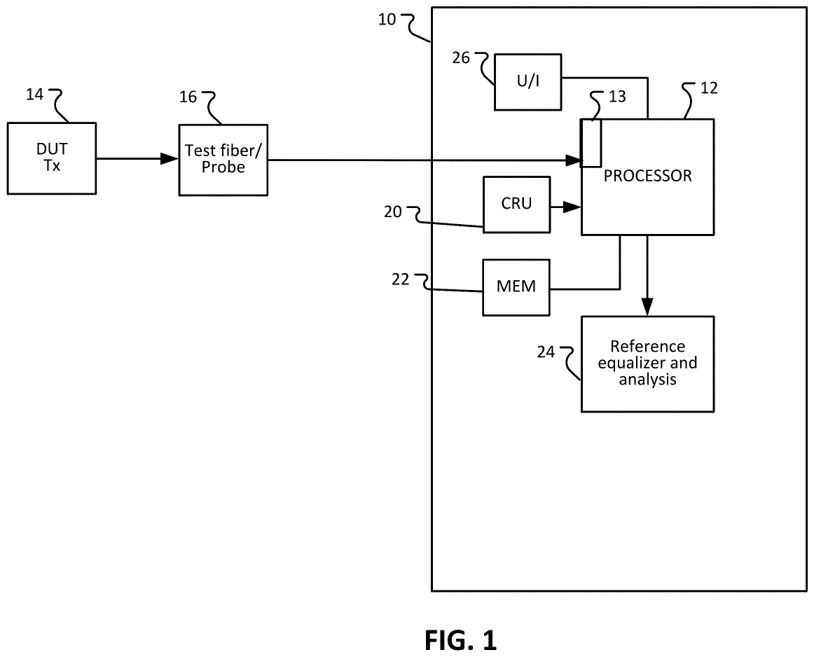

FIG. 1 shows an embodiment of a test and measurement instrument capable of deriving multiple step and impulse responses from waveforms. A device under test (DUT) 14 generates a waveform that the test and measurement instrument captures. The testing setup may include a test and measurement instrument such as an oscilloscope 10. The test and measurement instrument 10 receives a signal from the DUT 14 directly or through an instrument probe 16. In the case of an optical transmitter DUT, the probe will typically comprise a test fiber coupled to an optical to electrical converter, not shown, that provides a signal to the test and measurement instrument through one or more ports 13. Two ports may be used for differential signaling, while one port is used for single-ended signaling. The signals are sampled and digitized by the instrument to become waveforms. A clock recovery unit (CRU) 20 may recover the clock signal from the data signal if the test and measurement instrument 10 comprises a sampling oscilloscope for example. A software clock recovery can be used on a real-time oscilloscope.

The test and measurement instrument has one or more processors represented by processor 12, a memory 22 and a user interface 26. The memory may store executable instructions in the form of code that, when executed by the processor, causes the processor to perform tasks. User interface 26 of the test and measurement instrument allows a user to interact with instrument 10, such as to input settings, configure tests, etc. The test and measurement instrument may also include a reference equalizer and analysis module 24. The operations below may be performed by the one or more processors configured to execute code to perform the operations.

With single LFPR extraction, the DUT repetitively transmits the specified test pattern. The acquired waveform can be re-sampled to have M samples per UI (unit interval) using hardware or software clock recovery. The resampled and averaged pattern waveform is denoted as y(k). The symbols x(n) is aligned with y(k) such that the first M samples of y(k) correspond to the first symbol of the test pattern x(n), the second M samples of y(k) to the second symbol, and so on. If the pattern length is N, the M-by-N waveform matrix Y is defined as:

$$Y = [ \begin{matrix}y ( 1 ) & y ( M + 1 ) & … & y ( M ( N - 1 ) + 1 ) \\ y ( 2 ) & y ( M + 2 ) & … & y ( M ( N - 1 ) + 2 ) \\ … & … & … & … \\ y ( M ) & y ( 2 M ) & … & y ( MN )\end{matrix} ] \qquad ( 1 )$$

The symbols vector x is then rotated by the specified pulse delay Dₚ to yield xᵣ as shown in Equation (2):

$${x}_{r} = [ \begin{matrix}x ( {D}_{p} + 1 ) & x ( {D}_{p} + 2 ) & … & x ( N ) & x ( 1 ) & … & x ( N - {D}_{p} )\end{matrix} ] \qquad ( 2 )$$

The matrix X is defined to be an N-by-N matrix derived from xᵣ as shown in Equation (3):

$$X = [ \begin{matrix}{x}_{r} ( 1 ) & {x}_{r} ( 2 ) & … & {x}_{r} ( N ) \\ {x}_{r} ( N ) & {x}_{r} ( 1 ) & … & {x}_{r} ( N - 1 ) \\ … & … & … & … \\ {x}_{r} ( 2 ) & {x}_{r} ( 3 ) & … & {x}_{r} ( 1 )\end{matrix} ] \qquad ( 1 )$$

The matrix X₁ is defined to be the first Nₚ rows of X concatenated with a row vector of ones of length N. Nₚ is the specified length of the pulse. The M-by-(Nₚ+1) coefficient matrix, P, corresponding to the linear fit pulse response is then defined by Equation (4). The superscript “T” denotes the matrix transpose operator.

$$P = {{YX}_{1}^{T} ( {X}_{1} {X}_{1}^{T} )}^{- 1} \qquad ( 4 )$$

P₁ is defined as a matrix consisting of the first Nₚ columns of the matrix P as shown in Equation (5). The linear fit pulse response, p(k), is then read column-wise from the elements of P₁.

$${P}_{1} = [ \begin{matrix}p ( 1 ) & p ( M + 1 ) & … & p ( M ( {N}_{p} − 1 ) + 1 ) \\ p ( 2 ) & p ( M + 2 ) & … & p ( M ( {N}_{p} − 1 ) + 2 ) \\ … & … & … & … \\ p ( M ) & p ( 2 M ) & … & p ( M {N}_{p} )\end{matrix} ] \qquad ( 5 )$$

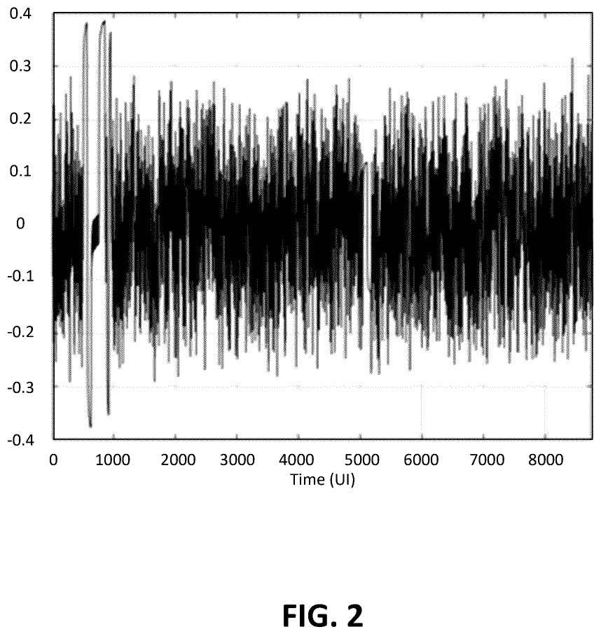

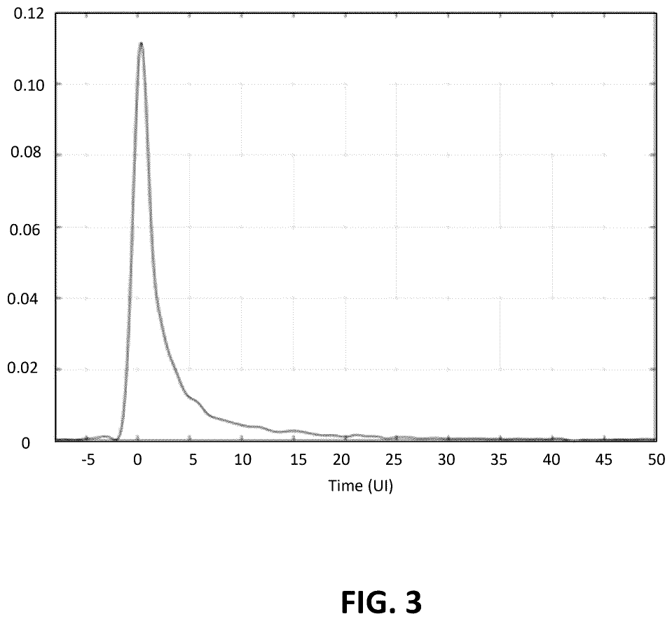

FIG. 2 illustrates a 64 GBaud PAM4 signal that has the averaged pattern waveform. The signal has large ISI because of the large channel loss. The single pulse extracted using the linear fit pulse response extraction method is shown in FIG. 3. For a PAM4 signal, the symbols 0, 1, 2, 3 are represented as the values of [−1 −⅓ ⅓ 1] in symbol vector x.

The following methodology describes an embodiment of determining step responses and impulse responses from the single pulse response. With the single pulse extraction result of the M-by-(Nₚ+1) coefficient matrix, P, in Equation (4), the step response can be derived as following. There are two possible step responses, one for rising step, one for falling step. In one embodiment, the process below gets the rising step response:
1. Define a symbol vector x_{risingStep} as long run of 0's followed by long run of 1's as shown in Equation (6). The run length can be set to be greater than Nₚ, for example Nₚ+1.

$${x}_{r i singStep} = [ \begin{matrix}0 & 0 & … & 0 & 1 & … & 1 & 1\end{matrix} ] \qquad ( 6 )$$

2. Rotate the symbol vector x=x_{risingStep} to create xᵣ as shown in Equation (2).
3, Create matrix X from the vector xᵣ as shown in Equation (3) and get the submatrix the matrix X₁ to be the first Nₚ rows of X concatenated with a row vector of ones of length N.
4. Compute the step response matrix Y_{risingStep} as:

$${Y}_{r i singStep} = {P}_{1} {X}_{1} \qquad ( 7 )$$

5. The rising step response, y_{risingStep}(k), is then read column-wise from the elements of the matrix Y_{risingStep}.

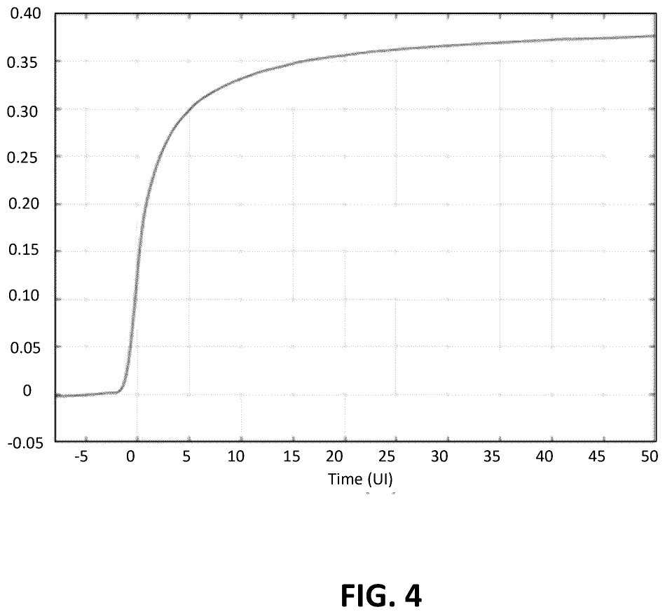

FIG. 4 shows a part of the rising step response derived through this process from the pulse response shown in FIG. 3. Note that it takes hundreds of UIs' time for this step to converge to high level, which is outside the plot range.

The process to get the falling step response is similar to the process to get the rising step response. Only change is in in the initial step in the process. Instead of using Equation (6), a symbol vector x_{fallingStep} is defined as long run of 1's followed by long run of 0's as shown in Equation (8).

$${x}_{fallingStep} = [ \begin{matrix}1 & 1 & … & 1 & 0 & … & 0 & 0\end{matrix} ] \qquad ( 8 )$$

The remaining steps are the same as in the process to derive the rising step response discussed above.

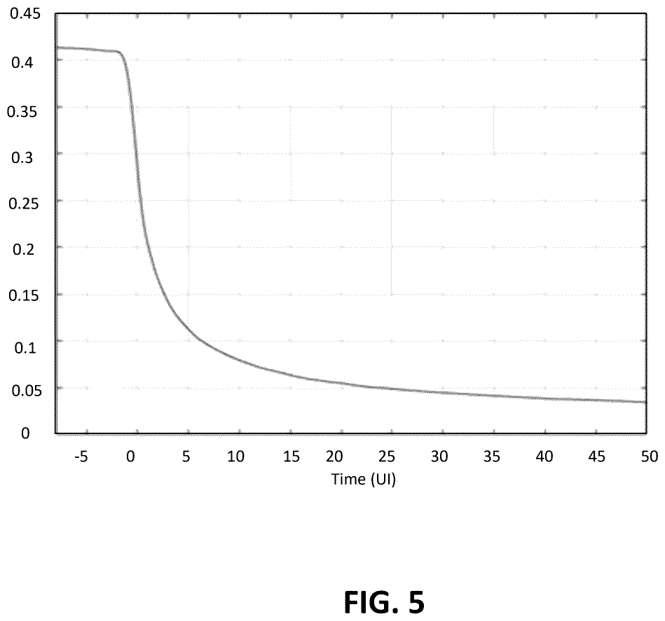

FIG. 5 shows a part of the falling step response derived from the pulse response shown in FIG. 3. Note that it takes hundreds of UIs' time for this step to converge to zero, which is outside the plot range.

The rising step responses and falling step responses are often asymmetrical in real-world applications. Analyzing these two distinct step responses offers a clearer insight into potential mismatches, allowing for more accurate system evaluation.

Once the step responses are obtained for rising and falling cases, the process finds the impulse responses. Impulse responses are the derivative of the step responses. For example:

$${y}_{risingImpulse} = \frac{{dy}_{risingStep}}{d k} \qquad ( 9 )$$

$$and$$

$${y}_{faillngImpulse} = \frac{{dy}_{fallingStep}}{dk} \qquad ( 10 )$$

The following describes multiple linear fit pulse response extraction. Some techniques involve the multiple linear fit pulse response method to get more detailed information of PAM4 signals. For example, the following procedure extracts multiple pulse responses for the 4 symbols in PAM4. Three linear fit pulses are extracted from the pattern waveform. One normalized pulse representing both symbol 0 and symbol 3, one normalized pulse for symbol 1 and one normalized pulse for symbol 2. Define the matrix X_{N}_{ₚ} to be the first Nₚ rows of X in Equation (3). The following three Nₚ-by-N switch matrices are defined for the three normalized pulses as

$${W}_{sym 0 \_ 3} = ( {X}_{{N}_{p}} == - 1 ) or ( {X}_{{N}_{p}} == 1 ) \qquad ( 11 )$$

$${W}_{sym 1} = ( {X}_{{N}_{p}} == - 1 / 3 )$$

$${W}_{sym 2} = ( {X}_{{N}_{p}} == 1 / 3 )$$

where the “ [symbol] ” operation returns a Boolean value. If the Boolean value of an element in the matrix is true, then the corresponding element in W_{sym} is set to 1. If the Boolean value is false, the element in W_{sym} is set to 0.

The following equation to calculate X_{sym} is used:

$${X}_{s y m} = [ \begin{matrix}{X}_{{N}_{p}} \cdot {W}_{sym 0 \_ 3} \\ {X}_{{N}_{p}} \cdot {W}_{sym 1} \\ {X}_{{N}_{p}} \cdot {W}_{sym 2} \\ ones , ( 1 , N )\end{matrix} ] \qquad ( 12 )$$

The following equation to calculate P_{sym} is used:

$${P}_{s y m} = {{YX}_{s y m}^{T} ( {X}_{s y m} {X}_{s y m}^{T} )}^{- 1} \qquad ( 13 )$$

Let P_{sym0_3} be the first Nₚ columns of P_{sym}, then P_{sym1} be the next Nₚ columns of P_{sym}, and P_{sym2} be the next Nₚ columns. The normalized linear fit pulse response for symbol 0 and symbol 3, P_{sym0_3}(k), is then read column-wise from the elements of P_{sym0_3}. The normalized linear fit pulse response for symbol 1, P_{sym1}(k), is read column-wise from the elements of P_{sym1}. The normalized linear fit pulse response for symbol 2, P_{sym2}(k), is read column-wise from the elements of P_{sym2}. The normalized pulses can be denormalized:

$${p}_{sym 0 \_ un \_ normalized} = - {p}_{sym 0 \_ 3} \qquad ( 14 )$$

$${p}_{sym 1 \_ un \_ normalized} = - \frac{1}{3} {p}_{sym 1}$$

$${p}_{sym {2}_{u {n}_{n o rmalized}}} = \frac{1}{3} {p}_{sym 2}$$

$${p}_{sym {3}_{u {n}_{n o rmalized}}} = {p}_{sym {0}_{3}}$$

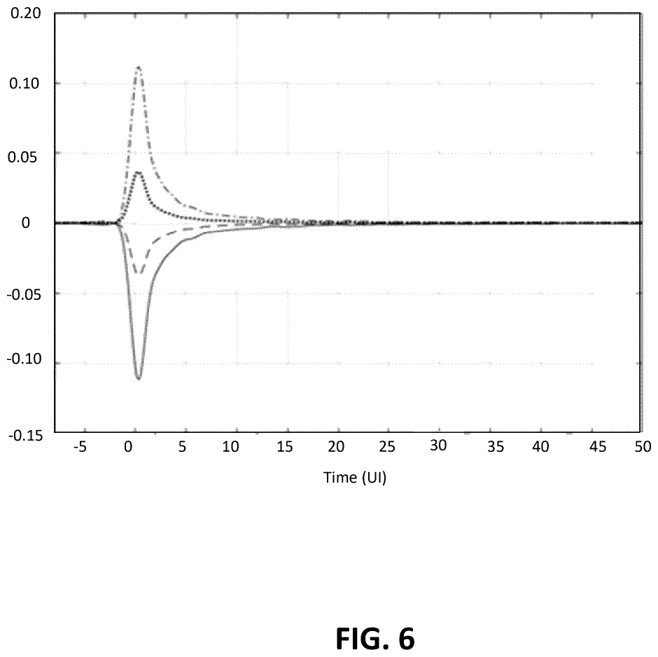

For the pattern waveform shown in FIG. 2, the denormalized pulses are shown in FIG. 6.

The following describes deriving multiple step responses and impulse responses from the multiple linear fit pulse responses. With the multiple linear fit pulse response extraction result of the M-by-(3Nₚ+1) coefficient matrix, P_{sym}, in Equation (13), the multiple step responses can be derived. For PAM4 signals, there are 12 possible step responses. For each of the 4 levels, there are 3 possible transitions to different levels. For example, starting from symbol 0, it can transition to symbol 1, symbol 2, symbol 3; starting from symbol 3, it can transition to symbol 0, symbol 1, symbol 2. To get one of the step responses, for example the step from symbol 0 to symbol 1:
1. Define a symbol vector x_{sym0_to_sym1_step} as long run of −1's (for symbol 0's) followed by long run of −⅓s (for symbol 1's) as shown in Equation (15). The run length can be set to be greater than Nₚ, for example Nₚ+1.

| | |
|---|---|
| ${x}_{sym0\_to \_sym1 \_step} = [ \begin{matrix}\begin{matrix}\begin{matrix}\begin{matrix}\begin{matrix}\begin{matrix}- 1 & - 1\end{matrix} & \begin{matrix}… & - 1\end{matrix}\end{matrix} & - \frac{1}{3}\end{matrix} & …\end{matrix} & - \frac{1}{3}\end{matrix} & - \frac{1}{3}\end{matrix} ]$ | (15) |

2. Rotate the symbol vector x=x_{sym0_to_sym1_step} to create xᵣ as shown in Equation (2).
3. Create matrix X from the vector xᵣ as shown in Equation (3) and get the submatrix the matrix X_{N}_{ₚ} to be the first Nₚ rows of X.
4. Construct matrix X_{sym} as shown in Equation (12).
5 Compute the step response matrix Y_{sym0_to_sym1_step} as.

$${Y}_{sym 0 \_ to \_ sym 1 \_ step} = {P}_{s y m} {X}_{s y m} \qquad ( 16 )$$

6. The rising step response, y_{sym0_to_sym1_step}(k), is then read column-wise from the elements of Y_{sym0_to_sym1_step}.

$${x}_{sym 0 \_ to \_ sym 2 \_ step} = [ \begin{matrix}- 1 & - 1 & … & - 1 & \frac{1}{3} & … & \frac{1}{3} & \frac{1}{3}\end{matrix} ] \qquad ( 17 )$$

To get the step response from symbol 0 to symbol 3, Equation (18) is used.

$${x}_{sym 0 \_ to \_ sym 3 \_ step} = [ \begin{matrix}- 1 & - 1 & … & - 1 & 1 & … & 1 & 1\end{matrix} ] \qquad ( 18 )$$

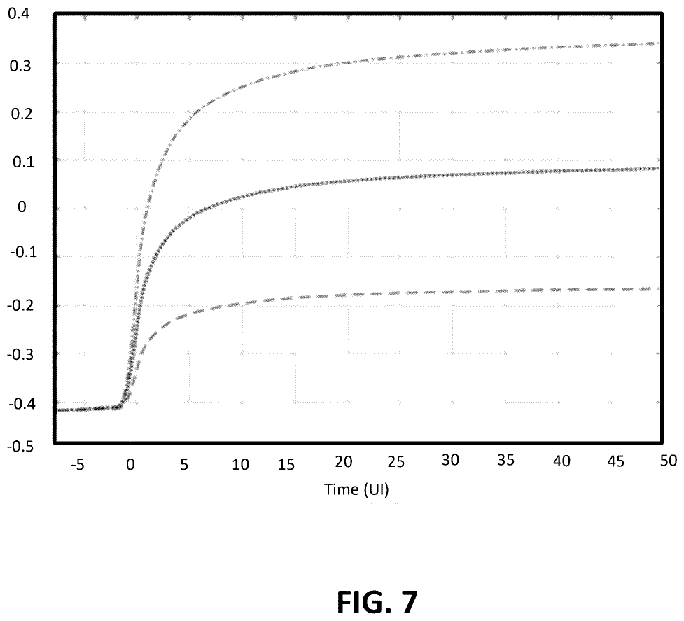

FIG. 7 shows a part of the rising step responses from symbol 0 to symbol 1, 2, 3 derived through this process from the multiple pulse responses in FIG. 6. Note that it takes hundreds of UIs' time for these steps to converge to the corresponding symbol's level, which is outside the plot range.

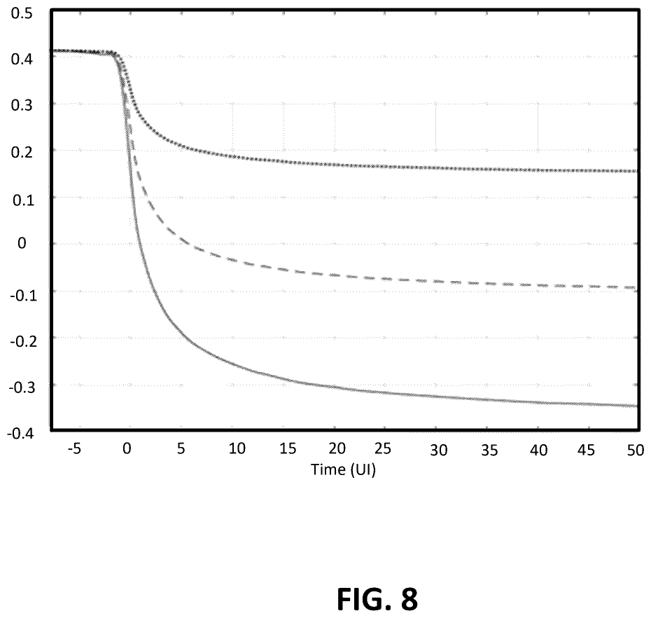

FIG. 8 shows a part of the falling step responses from symbol 3 to symbol 0, 1, 2 derived through this process from the multiple pulse responses in FIG. 6. Note that it takes hundreds of UIs' time for these steps to converge to the corresponding symbol's level, which is outside the plot range.

Once the step responses are obtained, the impulse responses are the derivatives of the step responses. For example:

$${y}_{sym 0 \_ to \_ sym 1 \_ impulse} = \frac{{dy}_{ym 0 \_ to \_ sym 1 \_ step}}{dk} \qquad ( 19 )$$

The present disclosure presents a method for deriving multiple step responses and impulse responses from PAM4 pattern waveforms. By complementing this analysis with the extraction of multiple pulse responses, one can gain deeper insights into signal and system behaviors. This comprehensive approach provides valuable information that enhances understanding and evaluation of high-speed communication systems. The method outlined in the present disclosure can also be extended to the analysis of various PAMn signals, broadening its applicability across different schemes.

As mentioned previously, analysis of step responses and impulse responses reveals distinct information about the signals and systems that pulse responses alone may not provide. Step responses are instrumental in determining the rise time of signals and are also pivotal for Time Domain Reflectometry (TDR) assessments of system impedance profiles. On the other hand, impulse responses, when transformed into the frequency domain via Fourier transform, provides crucial details about frequency-dependent channel loss and inter-symbol interference (ISI).

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement instrument, comprising: a port to allow the instrument to receive a signal from a device under test (DUT); one or more processors configured to execute code that causes the one or more processors to: acquire a waveform from the signal; derive a pattern waveform from the waveform using one of either hardware or software clock recovery; perform linear fit pulse response extraction on the pattern waveform to extract one or more linear fit pulse responses (LFPRs); determine at least one of one or more rising step responses and one or more falling step responses from each of the one or more LFPRs; evaluate the DUT based upon at least one of the one or more rising step responses and the one or more falling step responses; and adjust one or more of operation and design of the DUT based upon the evaluation.

Example 2 is the test and measurement instrument of Example 1, wherein the code that one or more processors to evaluate the DUT comprises code that causes the one or more processors to derive a rising impulse response from each rising step response and deriving a falling impulse response from each falling step response.

Example 3 is the test and measurement instrument of Example 2, wherein the code that causes the one or more processors to evaluate the DUT comprises code that causes the one or more processors to transform the rising impulse response and the falling impulse response into the frequency domain.

Example 4 is the test and measurement instrument of Example 3, wherein the code that causes the one or more processors to evaluate the DUT comprises code that causes the one or more processors to evaluate one or more of frequency-dependent channel loss and inter-symbol interference.

Example 5 is the test and measurement instrument of any of Examples 1 through 4, wherein the one or more LFPRs comprise multiple LFPRs.

Example 6 is the test and measurement instrument of Example 5, wherein the signal comprises a 4-level pulse-amplitude modulation (PAM4) signal.

Example 7 is the test and measurement instrument of Example 5, wherein the multiple LFPRs comprise three LFPRs, one LFPR for symbol 0 and symbol 3, one LFPR for symbol 1, and one LFPR for symbol 2.

Example 8 is the test and measurement instrument of Example 7, wherein the code that causes the one or more processors to extract one or more LFPRs comprises code that causes the one or more processors to normalize the three LFPRs prior to determining the step response.

Example 9 is the test and measurement instrument of any of Examples 1 through 8, wherein the code that causes the one or more processors to evaluate the DUT based upon at least one of the one or more rising step responses and the one or more falling step responses further comprises code that causes the one or more processors to perform time domain reflectometry analysis on at least one of the one or more rising step responses and the one or more falling step responses.

Example 10 is a method, comprising: receiving a signal from a device under test (DUT); acquiring a waveform from the signal; deriving a pattern waveform from the waveform using one of either hardware or software clock recovery; performing linear fit pulse response extraction on the pattern waveform to extract one or more linear fit pulse responses (LFPRs); determining at least one of one or more rising step responses and one or more falling step responses from each of the one or more LFPRs; evaluating the DUT based upon at least one of the one or more rising step responses and the one or more falling step responses from each one or more step responses; and adjusting one or more of operation and design of the DUT based upon the evaluation.

Example 11 is the method of Example 10, wherein evaluating the DUT comprises deriving a rising impulse response from each rising step response and deriving a falling impulse response from each falling step response.

Example 12 is the method of Example 11, wherein evaluating the DUT comprises transforming the rising impulse response and the falling impulse response into the frequency domain.

Example 13 is the method of Example 12, wherein evaluating the DUT comprises evaluating one or more of frequency-dependent channel loss and inter-symbol interference.

Example 14 is the method of any of Examples 10 through 13, wherein performing linear fit pulse response extraction on the pattern waveform comprises performing linear fit pulse response extraction to extract multiple LFPRs.

Example 15 is the method of Example 14, wherein the signal comprises a 4-level pulse-amplitude modulation (PAM4) signal.

Example 16 is the method of Example 15, wherein the one or more multiple LFPRs comprise three LFPRs, one LFPR for symbol 0 and symbol 3, one LFPR for symbol 1, and one LFPR for symbol 2.

Example 17 is the method of Example 16, wherein performing linear fit pulse response extraction to extract multiple LFPRs further comprises normalizing the three LFPRs prior to determining the step responses.

Example 18 is the method of any of Examples 10 through 17, wherein evaluating the DUT based upon at least one of the one or more rising step responses and the one or more falling step responses further comprises performing time domain reflectometry analysis on at least one of the one or more rising step responses and the one or more falling step responses.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
a port to allow the instrument to receive a signal from a device under test (DUT);
one or more processors configured to execute code that causes the one or more processors to:
acquire a waveform from the signal;
derive a pattern waveform from the waveform using one of either hardware or software clock recovery;
perform linear fit pulse response extraction on the pattern waveform to extract one or more linear fit pulse responses (LFPRs);
determine at least one of one or more rising step responses and one or more falling step responses from each of the one or more LFPRs;
evaluate the DUT based upon at least one of the one or more rising step responses and the one or more falling step responses; and
adjust one or more of operation and design of the DUT based upon the evaluation.

2. The test and measurement instrument as claimed in claim 1, wherein the code that one or more processors to evaluate the DUT comprises code that causes the one or more processors to derive a rising impulse response from each rising step response and deriving a falling impulse response from each falling step response.

3. The test and measurement instrument as claimed in claim 2, wherein the code that causes the one or more processors to evaluate the DUT comprises code that causes the one or more processors to transform the rising impulse response and the falling impulse response into the frequency domain.

4. The test and measurement instrument as claimed in claim 3, wherein the code that causes the one or more processors to evaluate the DUT comprises code that causes the one or more processors to evaluate one or more of frequency-dependent channel loss and inter-symbol interference.

5. The test and measurement instrument as claimed in claim 1, wherein the one or more LFPRs comprise multiple LFPRs.

6. The test and measurement instrument as claimed in claim 5, wherein the signal comprises a 4-level pulse-amplitude modulation (PAM4) signal.

7. The test and measurement instrument as claimed in claim 5, wherein the multiple LFPRs comprise three LFPRs, one LFPR for symbol 0 and symbol 3, one LFPR for symbol 1, and one LFPR for symbol 2.

8. The test and measurement instrument as claimed in claim 7, wherein the code that causes the one or more processors to extract one or more LFPRs comprises code that causes the one or more processors to normalize the three LFPRs prior to determining the step response.

9. The test and measurement instrument as claimed in claim 1, wherein the code that causes the one or more processors to evaluate the DUT based upon at least one of the one or more rising step responses and the one or more falling step responses further comprises code that causes the one or more processors to perform time domain reflectometry analysis on at least one of the one or more rising step responses and the one or more falling step responses.

10. A method, comprising:
receiving a signal from a device under test (DUT);
acquiring a waveform from the signal;
deriving a pattern waveform from the waveform using one of either hardware or software clock recovery;
performing linear fit pulse response extraction on the pattern waveform to extract one or more linear fit pulse responses (LFPRs);
determining at least one of one or more rising step responses and one or more falling step responses from each of the one or more LFPRs;
evaluating the DUT based upon at least one of the one or more rising step responses and the one or more falling step responses from each one or more step responses; and
adjusting one or more of operation and design of the DUT based upon the evaluation.

11. The method as claimed in claim 10, wherein evaluating the DUT comprises deriving a rising impulse response from each rising step response and deriving a falling impulse response from each falling step response.

12. The method as claimed in claim 11, wherein evaluating the DUT comprises transforming the rising impulse response and the falling impulse response into the frequency domain.

13. The method as claimed in claim 12, wherein evaluating the DUT comprises evaluating one or more of frequency-dependent channel loss and inter-symbol interference.

14. The method as claimed in claim 10, wherein performing linear fit pulse response extraction on the pattern waveform comprises performing linear fit pulse response extraction to extract multiple LFPRs.

15. The method as claimed in claim 14, wherein the signal comprises a 4-level pulse-amplitude modulation (PAM4) signal.

16. The method as claimed in claim 15, wherein the one or more multiple LFPRs comprise three LFPRs, one LFPR for symbol 0 and symbol 3, one LFPR for symbol 1, and one LFPR for symbol 2.

17. The method as claimed in claim 16, wherein performing linear fit pulse response extraction to extract multiple LFPRs further comprises normalizing the three LFPRs prior to determining the step responses.

18. The method as claimed in claim 10, wherein evaluating the DUT based upon at least one of the one or more rising step responses and the one or more falling step responses further comprises performing time domain reflectometry analysis on at least one of the one or more rising step responses and the one or more falling step responses.
